(19) United States
(12) Patent Application Publication
(10) Pub. No.: US 2012/0196029 A1
(43) Pub. Date: Aug. 2, 2012

(54) APPARATUS AND METHOD OF FORMING A UNIFORM GRID LINE

(75) Inventor: Mark Kevin Nelson, Commerce Township, MI (US)

(73) Assignee: EXATEC, LLC, Wixom, MI (US)

(21) Appl. No.: 13/355,684

(22) Filed: Jan. 23, 2012

Related U.S. Application Data
(60) Provisional application No. 61/436,914, filed on Jan. 27, 2011.

(51) Int. Cl. H05K 3/14; B05C 5/02

(52) U.S. Cl. 427/8; 118/696

(57) ABSTRACT

A method for forming a conductive trace on a panel can comprise: determining a height between a sensor and a surface of the panel, adjusting the height if the height does not equal a desired height by creating relative motion between the nozzle and the panel, creating relative motion between the nozzle and the panel in the y direction, and dispensing a conductive ink from the nozzle onto the surface of the panel from a piston dispenser at a rate controlled by a flow regulator to form the conductive trace. The sensor can be in operable communication with a controller and be located a distance of less than or equal to 5 mm from a point where a nozzle dispenses the conductive ink onto the panel. The conductive trace has a uniform width.

### CROSS REFERENCE TO RELATED APPLICATIONS

This application claims priority to U.S. Provisional Application Ser. No. 61/436,914, filed on Jan. 27, 2011, which is incorporated by reference in its entirety.

### BACKGROUND

Disclosed herein is an apparatus and method of forming a conductive heater grid design on transparent glazing panels, such as those used as backlights in vehicles.

Plastic materials, such as polycarbonate (PC) and polymethylmethyacrylate (PMMA), are currently being used in the manufacturing of numerous automotive parts and components, such as B-pillars, headlamps, and sunroofs. Automotive rear window (backlight) systems represent an application for these plastic materials due to their many identified advantages, particularly in the areas of styling/design, weight savings, and safety/security. More specifically, plastic materials offer the automotive manufacturer the ability to reduce the complexity of the rear window assembly through the integration of functional components into the molded plastic system, as well as the ability to distinguish their vehicles by increasing overall design and shape complexity.

Although there are many advantages associated with implementing plastic windows, these windows are not without limitations that represent technical hurdles that must be addressed prior to wide-scale commercial utilization. Limitations relating to material properties include the stability of plastics during prolonged exposure to temperature extremes, e.g., elevated temperatures and below freezing temperatures, as well as the limited ability of plastics to conduct heat. Regarding the latter, in order to be used as a backlight in a vehicle, the plastic material must be compatible with the use of a defroster or defogging system (hereafter just referred to as a “defroster”). For commercial acceptance, a plastic backlight must meet the performance criteria established for the defrosting or defogging of glass backlights.

The difference in material properties between glass and plastics becomes quite apparent when considering heat conduction. The thermal conductivity of glass (T_{c}=22.39×10⁻⁴ cal/cm-sec-° C.) is approximately 4-5 times greater than that exhibited by a typical plastic (e.g., T_{c}, for polycarbonate=4.78×10⁴ cal/cm-sec-° C.). Thus, a defroster designed to work effectively on a glass window may not necessarily be efficient at defrosting or defogging (hereafter just “defrosting” or “defrost”) a plastic window. The lower thermal conductivity of the plastic limits the dissipation of heat from the heater grid lines across the surface of the plastic window compared to dissipation across a glass window. Thus, at a similar power output, a heater grid on a glass window can defrost the entire viewing area, while the same heater grid on a plastic window may only defrost those portions of the viewing area that are close to the grid lines.

A second difference between glass and plastics that must be overcome is related to the electrical conductivity exhibited by a printed heater grid. The thermal stability of glass, as demonstrated by a relatively high softening temperature (e.g., T_{soften}>>1,000° C.), allows for the sintering of a metallic paste onto the surface of the glass window to yield a substantially inorganic frit or metallic wire. Since the sintering temperature of the metallic paste is greater than the glass transition temperature (T_{g}) of a typical plastic resin (e.g., polycarbonate T_{g}=145° C.), a metallic paste cannot be sintered onto a plastic panel. Rather, it must be cured on the panel at a temperature lower than the T_{g}, of the plastic resin.

A metallic paste typically consists of metallic particles dispersed in a polymeric resin that will bond to the surface of the plastic to which it is applied. The curing of the metallic paste provides a conductive polymer matrix having closely spaced metallic particles dispersed throughout a dielectric layer. However, the presence of the dielectric layer (e.g., polymer) between dispersed conductive particles leads to a reduction in the conductivity, or an increase in resistance, of the cured heater grid lines, as compared to dimensionally similar heater grid lines sintered onto a glass substrate. This difference in conductivity manifests itself in poor defrosting characteristics exhibited by the plastic window, as compared to the glass window.

With the above in mind, it is clear that controlling the quality of the heater grid printed onto the panel is important in maximizing the efficiency and effectiveness of any defroster used with that panel. Various parameters affect the quality of the printed heater grid and these parameters include any variances in the cross-sectional area (e.g., width and height). The more variances that exist in width and height, the greater the negative impact on the effectiveness of the defroster. This is a result of unequal resistances in various sections of the grid line and busbars resulting in unequal resistive heating in various sections of the defroster. With regard to straightness, this is mainly an aesthetic concern that becomes more of an issue because of the ability of plastic window assemblies to have greater design flexibility and curvature.

A defroster may be printed directly onto the surface inner or outer of a panel, or on the surface of a protective layer, using a conductive ink or paste and various methods such as screen-printing, ink jet printing, and automatic dispensing. Automatic dispensing, for example, includes various types of adhesive application, such as drip & drag, streaming, and simple flow dispensing. In each of the above instances, the shape of the panel impacts the quality of the printed lines, i.e., screen printing becomes very difficult on non-planar panels.

From the above, it is seen that there is a need in the industry for an apparatus and method that can effectively control the quality and consistency with which grid lines are printed onto a panel.

### SUMMARY

Disclosed herein are apparatus and methods for forming uniform grid lines on a panel, and articles made therefrom.

In one embodiment, an apparatus for forming a uniform grid line on a panel comprises: a piston dispenser having a nozzle for dispensing a conductive ink onto a panel, a height sensor in operable communication with the dispenser and positioned to sense the surface of the panel during use at a distance of less than or equal to 5 mm from a point where the nozzle dispenses the conductive ink onto the panel, an actuator configured to create relative motion between the dispenser and the panel, a flow regulator coupled to the conductive ink source so as to regulate a flow rate of conductive ink out of the nozzle during use; and a controller in operational communication with the dispenser, height sensor, actuator, and flow regulator. The nozzle is connected to a conductive ink source. During use, the controller can cause relative motion between the panel and the nozzle, in a predetermined pattern across a surface of the panel in a y-direction, and/or can control the distance in the z-direction between the nozzle and the panel based upon a signal from the height sensor.

A method for forming a conductive trace on a panel can comprise: determining a height between a sensor and a surface of the panel, adjusting the height if the height does not equal a desired height by creating relative motion between the nozzle and the panel, creating relative motion between the nozzle and the panel in the y-direction, and dispensing a conductive ink from the nozzle onto the surface of the panel from a piston dispenser at a rate controlled by a flow regulator to form the conductive trace. The sensor can be in operable communication with a controller and positioned to sense the surface of the panel at a distance of less than or equal to 5 mm from a point where a nozzle dispenses the conductive ink onto the panel. The conductive trace has a uniform width.

Further features will become readily apparent after a review of the following description, with reference to the drawings and claims that are appended to and form a part of this specification.

### BRIEF DESCRIPTION OF THE DRAWINGS

The following is a brief description of the drawings wherein like elements are numbered alike and which are presented for the purposes of illustrating the exemplary embodiments disclosed herein and not for the purposes of limiting the same.

FIG. 1 is a graphical representation of auger performance, namely auger output versus auger rotary speed.

FIG. 2 is a schematic representation of an embodiment of a grid line path points.

FIG. 3 is a schematic representation of an embodiment of a partial grid line path points.

FIG. 4(A) is a schematic top view of a transition zone for a grid line.

FIG. 4(B) is a side view of the grid line taken along lines B-B of FIG. 4(A).

FIG. 4(C) is a side view of the grid line taken along lines A-A of FIG. 4(A) showing a wider and taller grid line than illustrated in FIG. 4(B).

FIG. 5 is a top view of an exemplary grid line design having zones of different resistance.

FIG. 6 is a graphical representation an embodiment of a robot speed profile.

FIG. 7 is a graphical representation of another embodiment of a robot speed profile.

FIG. 8 is a schematic of an embodiment of a dispensing system.

FIG. 9 is schematic of another embodiment of a dispensing system.

FIG. 10 is a schematic cross-sectional view of four alternative embodiments of a backlight assembly.

### DETAILED DESCRIPTION

Formation of a heater grid is a balance of several factors, including the requirement for uniformity versus the practical consideration of production speed. Uniformity is an important characteristic since it affects both aesthetics and function; e.g., affecting resistance and hence heating results. The present system and method can attain a uniform grid line, i.e., having a uniform width along its entire length. Uniform as used herein is a deviation from the target width of the particular zone of less than or equal to 20%. In other words, for a target width of 1.0 mm, the deviation would be less than or equal to ±0.2 mm. The acceptable tolerances are when forming grid lines are small. Grid lines (also known as traces) generally have a width of less than or equal to 3.0 millimeters (mm), specifically less than or equal to 2.0 mm, e.g., a width of 0.5 mm to 1.2 mm, and a height of less than or equal to 0.5 mm from the substrate (e.g., panel) surface, specifically, less than or equal to 0.1 mm from the substrate surface, e.g., a height of 0.025 mm to 0.05 mm. In some systems that employ an auger dispenser, the resultant grid lines, having a target width of 0.7 mm, have an actual width of 0.5 mm to 1.3 mm. In other words, the actual width exceeds the desired tolerance by greater than or equal to 100% (e.g., the width along the length of the grid line can vary with areas having a variance of greater than or equal to 85% of the desired grid line width). With the present system having the sensor measurement adjacent to point where the paste will be dispensed (e.g., an offset distance of less than or equal to 5 mm, specifically less than or equal to 4 mm, more specifically, less than or equal to 2 mm, and yet more specifically, less than or equal to 1.5 mm), and the piston dispenser a uniform grid line can be formed. Furthermore, it is possible to apply the paste to the panel at a rate of greater than or equal to 100 millimeters per second (mm/sec) (specifically, greater than or equal to 200 mm/sec, and even greater than or equal to 400 mm/sec) and yet still attain the uniform grid lines. The speed at which printing is done affects both the width and height of the grid lines.

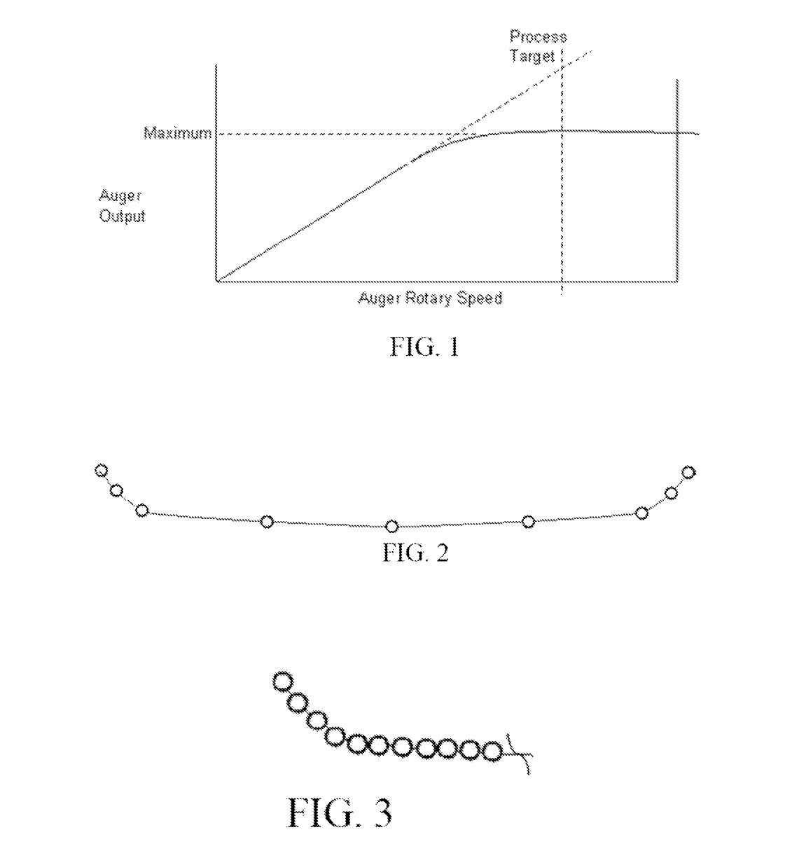

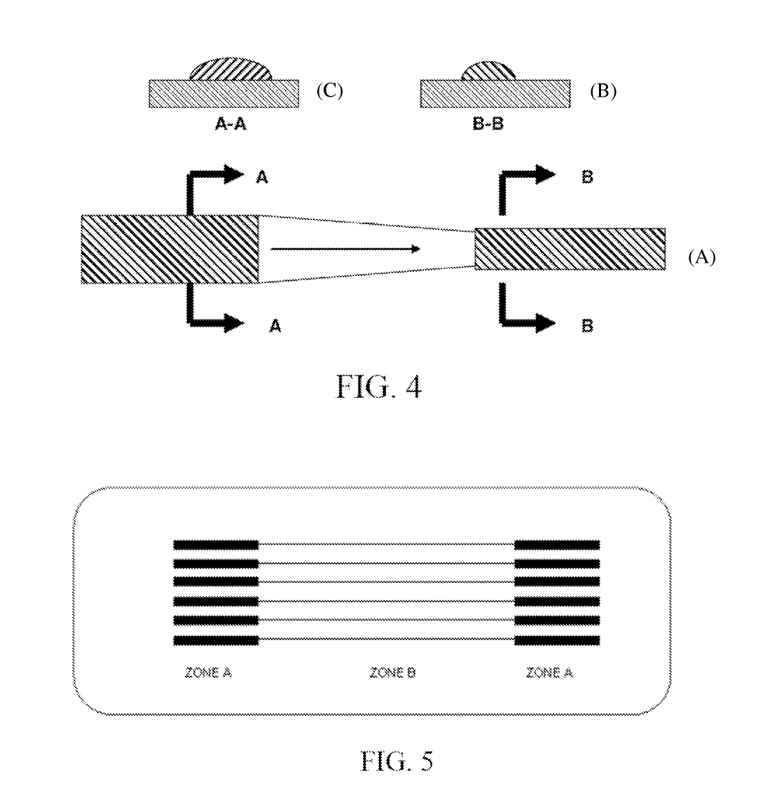

It is understood that adjusting the rheology can effect faster rates, but there is a limit in the amount of adjustment possible. The rheology of the paste is a balance between having sufficient structural integrity to retain the desired geometry when formed as a grid line (e.g., does not drip, run, or otherwise deform), and a viscosity that allows facile dispensing. Also, it was discovered that an auger dispensing device was a rate limiting factor. The auger dispensing device, particularly at the necessary tolerances, failed to produce a linear response to output across the entire dispensing speed needs (see FIG. 1). Hence, it produced inconsistent grid line resistance and poor repeatability. The auger volumetric output was limited. To achieve the desired linear speed, it was necessary to spin the auger at high rate. It was discovered that, when trying to dispense lots of paste quickly, a maximum volumetric output was achieved despite the revolutions per minute (RPM) of the auger. Furthermore, the output was sometimes spotty, had bubbles, or was variable in volume per linear distance. Also, axial play between the auger lead screw and the auger barrel was a transient problem in the auger assembly. This axial play caused inconsistent volumetric paste output, which, in turn, caused inconsistent grid line resistivity from run-to-run. One solution to this problem was to monitor the wear on the components and to replace the components to eliminate axial play between the lead screw and the auger barrel. Although this could be effective, it did not solve the problem of the limitation in volumetric output and was not efficient in a manufacturing environment.

In order to further enhance the speed of the system and to enable the robot to produce the uniform grid lines, additional path points (e.g., position points along the path where the paste is to be dispensed) were programmed along the spline path where the paste was to be applied. The additional path points enabled the robot to have a faster acceleration and deceleration while retaining high path precision (e.g., while producing uniform grid lines). Path points can also, or alternatively, be strategically located to enable rapid acceleration and rapid deceleration at predetermined times. For example, to enable acceleration while oriented in one busbar area, and enable deceleration in another busbar area. As a result, dispensing rate can be constant over a desired zone of the grid line, for example, over Zone A and/or Zone B of FIG. 5.

The height and/or width, and hence the volume, of the grid lines, can be varied to control the resistivity over the length or in a section of the grid lines. This can be used to achieve a current density for electrical and thermal performance. It may be desirable to increase the volume of a grid line to reduce the power and alleviate a “hot spot” in a particular portion of the grid. In current automotive defroster designs, the grid lines can have a larger width near a busbar adjacent either end of the defroster and a taper to a smaller width in the center of the grid between busbars. A larger volume can be built near the busbars with a smaller volume near the center of the grid lines between the busbars. Therefore, in some cases, as opposed to a grid line that is a single size (between the busbars), some embodiments have a controlled variation of grid line width to create zones of different resistance in the defroster pattern, e.g., see FIG. 5. This zone functionality can be accomplished by dispensing more or less volume of paste, on command, along the grid line. Changing the volume of grid line paste changes the grid line resistance at the location desired in the pattern. The volume can be varied by changing the height, and/or amount of conductive ink (paste) dispensed to make the grid lines. Changing the height of the traces requires dispensing the ink (also referred to herein as paste) at a greater height, which may result in decreased line quality (i.e. waviness or meandering). Changing the volume by increasing or decreasing the amount of conductive ink dispensed is also problematic since adjusting the rate of ink delivery is difficult with current systems, often requiring hardware changes in the middle of dispensing the grid that require downtime and increase production costs. Changing the width and/or height can also be accomplished by “re-tracing”, i.e., dispensing a grid line, then dispensing again one or more times on specific portions of the grid line to form thicker portions (e.g., multiple passes), there are disadvantages. For example, due to the re-tracing, there was an interface between each of the dispensed layers of paste which contributed to the fragility of the grid line. Using the piston dispenser enables faster rates while attaining a uniform grid line. This can be used in combination with the strategically located path points (e.g., strategically provided control signals). For example, programmably changing the volume per unit length of paste via robot speed changes and/or piston output changes can change resistivity.

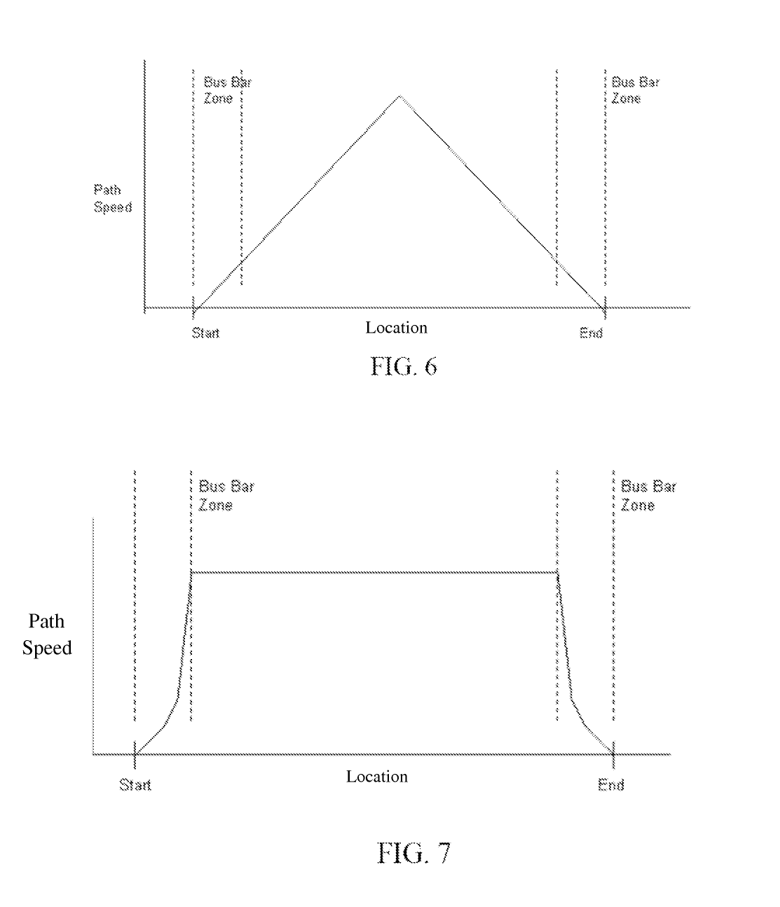

Further uniformity was possible by adjusting the control algorithm of the robot path so as to orient the acceleration and deceleration of the nozzle over a specific area of the path, e.g., over the busbars. For example, as can be seen in FIG. 6, path speed can vary across the grid line. For example, outside of the busbar zone the speed can increase and/or decrease. As is illustrated, the speed can accelerate to the center of the grid line and decelerate toward the end of the opposite busbar zone. Such a method, however, requires a high degree of output control since the rate of motion is changing across the grid line, the output of paste must also change in an attempt to attain a uniform grid line.

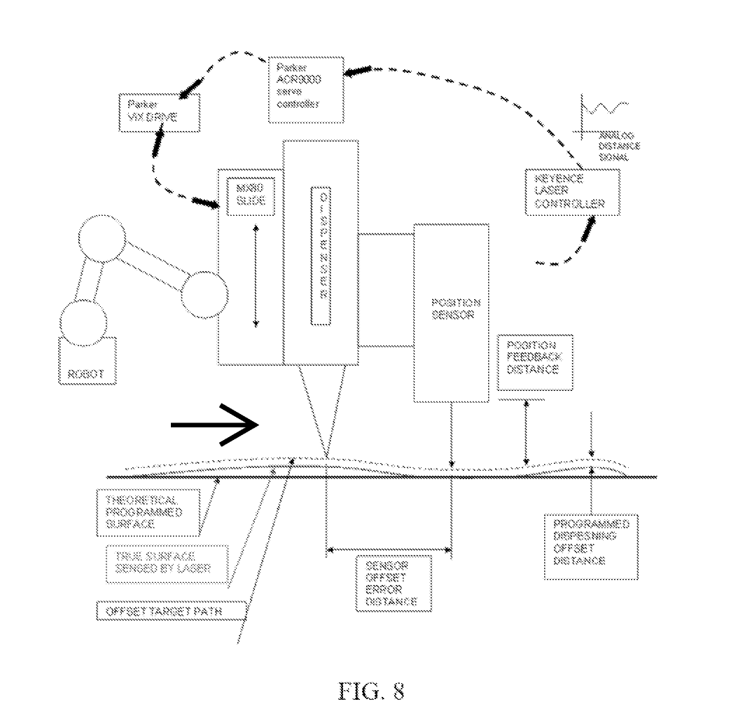

FIG. 7 illustrates an embodiment where the control across the grid line is not variable and hence can be more accurate. For example, the maximum path speed is reached in the busbar zone, the speed across the grid line location is constant, and then deceleration occurs in the opposite busbar zone.

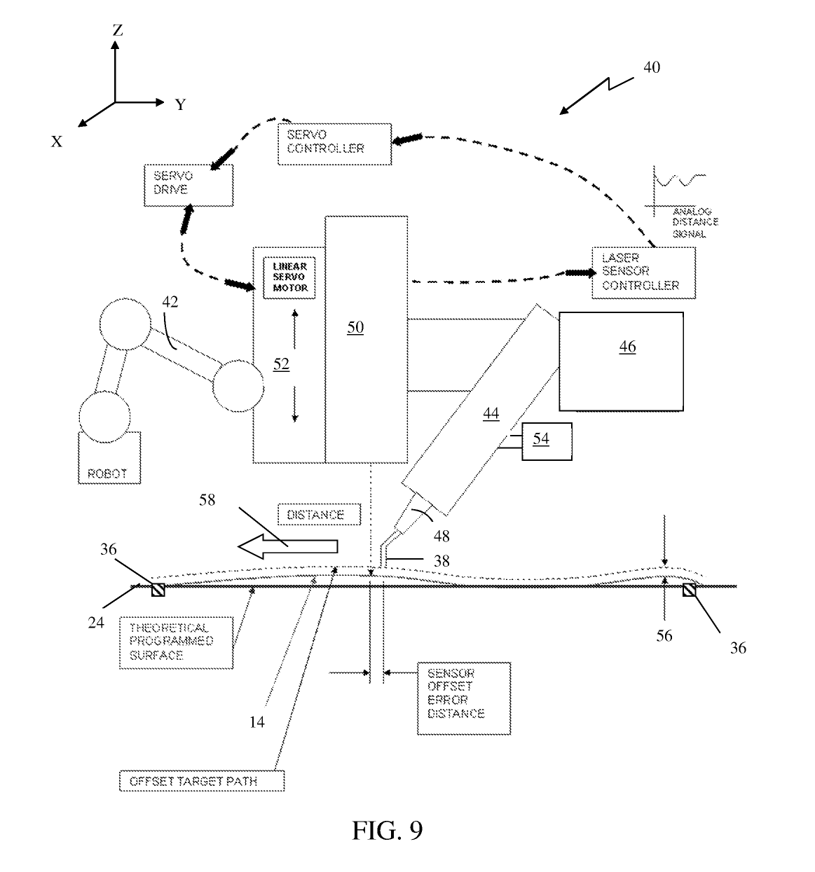

The ability to attain the uniformity is affected by slight variances in the surface of the part, e.g., a variance of up to 5 mm or so (e.g., 2 mm to 5 mm), wherein the variance is relative to a nominal surface (i.e., that the robot expects based upon the programmed information). As can be seen in FIG. 8, the sensor offset error distance can inhibit the controller from adjusting the nozzle to accurately adjust for surface variations. Generally, the distance between the sensor measurement and the dispensing paste is 15 mm to 20 mm. As can be seen in FIG. 9, the position of the laser sensor was changed to reduce the offset distance (i.e., the distance between the sensor reading location and the nozzle dispensing location) to less than or equal to 5 mm, specifically less than or equal to 3 mm, and yet more specifically, less than or equal to 1 mm. Furthermore, the sensor can be oriented at an attitude to the surface based upon the type of sensor. For example, a laser sensor can be oriented at 15-20 degrees with respect to the surface, while an ultrasonic sensor can be oriented perpendicular to the surface.

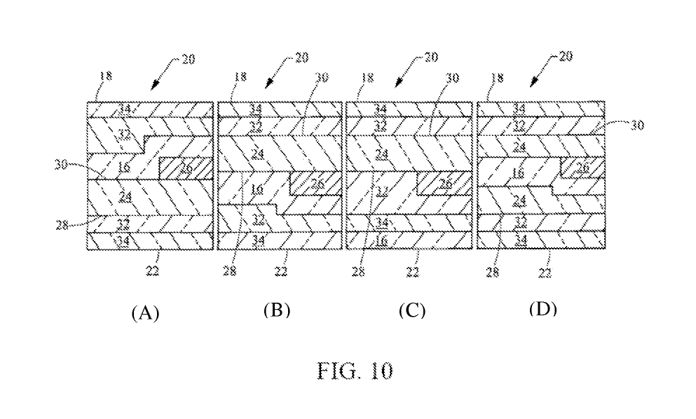

Referring now to the drawings and as seen in FIG. 10, a defroster or heater grid 16 can be positioned near the external surface 18 of a plastic window assembly 20 (Schematic A), on an internal surface 22 of the plastic window assembly 20 (Schematic C), or encapsulated within the plastic panel (Schematic D) itself. Each of the possible positions for the heater grid 16 offers different benefits in relation to overall performance and cost. Positioning the heater grid 16 near the external surface 18 (Schematic A) of the window assembly 20 can minimize the time necessary to defrost the window assembly 20. Positioning the heater grid 16 on the internal surface 22 (Schematic B and C) of a plastic panel 24 of the window assembly 20 offers benefits in terms of ease of application and lower manufacturing costs.

The transparent plastic panel 24 itself can be constructed of any thermoplastic polymeric resin(s). Exemplary thermoplastic resins include, polycarbonate resins, acrylic resins, polyarylate resins (e.g., polymethylmethyacrylate (PMMA)), polyester resins, and polysulfone resins, as well as combinations comprising at least one of the foregoing. The panels 24 can be formed into a window through the use of various techniques, such as molding, thermoforming, extrusion, and so forth. Optionally, the panels 24 can further include areas of opacity. For example, an opaque ink or the like can be applied (e.g., printed) on the panel 24 in the form of a black-out border 26 or molding a border using an opaque resin.

The heater grid 16 can be printed directly onto the inner surface 28 or outer surface 30 of the plastic panel 24. Alternatively, it can be printed on the surface of one or more protective layers 32, 34. In either construction, printing is affected using a conductive ink.

In its final construction, the plastic panel 24 can be protected from such natural occurrences as exposure to ultraviolet radiation, oxidation, and abrasion, through the use of protective layer(s), e.g., a single protective layer 32 or additional, optional protective layers 34, both on the exterior side and/or interior side of the panel 24. As the term is used herein, a transparent plastic panel with protective layer(s) is a transparent plastic glazing panel.

The protective layers 32, 34 can be a plastic film, an organic coating, an inorganic coating, or a combination comprising at least one of the foregoing. The plastic film can be of the same or different composition as the transparent panel. Examples of organic coatings include urethanes, epoxides, and acrylates, as well as combinations comprising at least one of the foregoing. Some examples of inorganic coatings include silicones, aluminum oxide, barium fluoride, boron nitride, hafnium oxide, lanthanum fluoride, magnesium fluoride, magnesium oxide, scandium oxide, silicon monoxide, silicon dioxide, silicon nitride, silicon oxy-nitride, silicon oxy-carbide, silicon carbide, tantalum oxide, titanium oxide, tin oxide, indium tin oxide, yttrium oxide, zinc oxide, zinc selenide, zinc sulfide, zirconium oxide, zirconium titanate, and glass, as well as combinations comprising at least one of the foregoing.

The plastic panel and/or the protective layer(s) can comprise additive(s) to modify optical, chemical, and/or physical properties. Some possible additives include for example, mold release agents, ultraviolet light absorbers, stabilizers (such as light stabilizers, thermal stabilizers, and so forth), lubricants, plasticizers, rheology control additives, pigments, dyes, colorants, dispersants, anti-static agents, blowing agents, flame retardants, impact modifiers, among others, such as transparent fillers (e.g., silica, aluminum oxide, etc.) to enhance abrasion resistance. The above additives can be used alone or in combination with any other additive.

The protective layer(s) can be applied by any suitable technique. Exemplary techniques include deposition from reactive species, such as those employed in vacuum-assisted deposition processes, and atmospheric coating processes, such as those used to apply sol-gel coatings to substrates. Examples of vacuum-assisted deposition processes include plasma enhanced chemical vapor deposition, ion assisted plasma deposition, magnetron sputtering, electron beam evaporation, and ion beam sputtering. Examples of atmospheric coating processes include curtain coating, spray coating, spin coating, dip coating, and flow coating, as well as combinations comprising at least one of the foregoing. The protective layer(s) can be applied via any technique or combination comprising at least one of the foregoing.

As an illustrative example, a polycarbonate panel 24 comprising the Exatec* 900 automotive window glazing system with a printed defroster 16 generally corresponds to the embodiment of Schematic C of FIG. 10. In this particular case, the transparent panel 24 is polycarbonate and is protected with a multilayer coating system (Exatec* SHP-9X, Exatec* SHX), and a deposited layer of a “glass-like” coating (SiOₓ,C_{y},H_{z}) that is then printed with a heater grid 16 on the exposed surface of the protective layer 34 facing the interior of the vehicle. As a further alternative construction, a heater grid 16 can be placed on top of protective layer(s) (e.g., layers 32, 34), and then over-coated with additional protective layer(s). For instance, a heater grid 16 can be placed on top of a silicone protective coating (e.g., AS4000, commercially available from GE Silicones) and subsequently over-coated with a “glass-like” film.

Turning now back to FIG. 9, which illustrates one example of an apparatus 40, which can be a manipulator (e.g., robotic arm device), for dispensing conductive ink 38 upon the panel 24 (or glazing), to form a series of heater grid lines such as illustrated in FIG. 5. The apparatus 40 includes a robot arm 42, with a dispenser 44 (e.g., an air pressure piston dispenser comprising a reservoir, needle tip, and piston) attached to the robot arm 42. A controller (comprising the laser sensor controller, the servo controller, and the servo drive), is in operable communication to the robot arm 42, the dispenser 44. For example, the sensor can provide an analog voltage feedback signal to the linear servo controller, the signal can be used to guide the manipulator (e.g., linear servo motor) up/down to follow surface at a desired offset distance. A flow regulator 46 is in operable communication with the dispenser 44, and hence the ink source.

The flow regulator 46 can be any device capable of controlling the flow rate of paste (e.g., conductive ink) from the source (e.g., conductive ink source) 54 to the nozzle 48. For example, the flow regulator can be a dispensing controller, e.g., wherein the air pressure is set constant, and the controller is sued to turn on/off air via an internal solenoid valve. Additionally, or alternatively, the robot will sense the current tip location on path and issue a change to an analog voltage output signal. The analog output signal will control an “I/P controller” or air regulator controlled by analog signal in order to change the pressure applied to the dispenser reservoir on command. For on/off control of the applied air pressure, and therefore paste stream output, the output air pressure can be controlled through a solenoid valve.

Relative motion can be created between the dispenser 44 (e.g., between the nozzle 48) and the surface 14 of the panel 24, with the nozzle moving in the direction of the arrow 58 relative to a panel motion in the opposite direction. For example, the robot arm 42 can be articulatable and capable of moving the nozzle 48 to any point on the surface 14 of the panel 24. Other examples of the machine 40 for dispensing a conductive material include those provided in U.S. Patent Publication 2007/0175175-A1, filed on Dec. 29, 2005. Alternatively, or in addition, the nozzle 48 can remain stationary while the panel 24 articulated to move relative to the nozzle 48. In yet another embodiment, both the nozzle 48 and panel 24 move relative to one another.

For example, the robot arm 42 can move the dispenser 44 and hence the nozzle 48 in a linear direction across the panel 24 as the dispenser 44 dispenses the conductive ink through the nozzle 48 onto the panel 24 to form the heater grid lines. As is shown in the figure, the dispenser 44 can be supported by the robot arm 42. Coupled to the robot arm 42 is a sensor 50 and an actuator 52. During operation, the flow regulator controls the dispensing of the conductive ink through the nozzle 48, onto the internal surface 14. To minimize weeping/drooling and excessive material buildup at printing starts and stops, the flow of material may be reversed by the flow regulator to “suckback” and prevent dispensing of excessive material. This can be accomplished in a variety of ways such as applying a vacuum to cancel applied pressure and resultant force on the piston.

To ensure the ink is dispensed in a manner to form grid lines of the desired uniformity and zone(s) of the desired width and height, the sensor 50, directly or indirectly, measures the distance of the dispensing head 48 from the surface 14. As a result, the controller, while controlling the location of the nozzle (e.g., controlling the robot arm 42 to move the dispenser 44 to a desired position over the surface 14), actively controls a z-axis position (height relative to the panel 24) of the nozzle 48 (e.g., using the actuator 52 based on input from the sensor 50). For example, the manipulator (e.g., robot) can be controlled by one controller, with the linear servo motor controlled by another controller. The manipulator controller may communicate with a servo controller, either directly or indirectly thru a higher-level “master controller” that oversees (e.g., controls) all components. The actuator 52 translates the position of the nozzle 48 to within a precise height 56 along the z-axis. (see FIG. 9) The height can be less than or equal to 6 millimeters (mm), specifically, 2 mm to 5 mm, and more specifically 4 mm, from the surface 14. Optionally, the height can be less than or equal to 2 mm (e.g., less than or equal to 1 mm) as a start up height, and then transition to an operating height that is greater than the start-up height (e.g., is 3 mm to 5 mm). While the actuator 52 can be any electric, hydraulic, pneumatic, piezoelectric, and/or electromagnetic, or other actuator 52 capable of similar precision and response time, e.g., can be a linear servo motor. Alternatively, or in addition, the actuator 52 can be attached to a support 36 to articulate the support 36 (and hence the panel 24) in the z-axis relative to the nozzle 48.

The sensor 50 is any sensor capable of measuring a height 56 from the true surface 22 (surface sensed by the laser). Since the panel is generally transparent plastic, the sensor is capable of measuring relative to a semi-reflective and/or transparent surface. While the exemplary sensor 50 is a laser triangulation sensor, any other non-contact sensor 50 capable of the accuracy and tolerances could also be used, such as an ultrasonic sensor. Exemplary sensors include a photonic sensor (i.e. measures the intensity of the reflected light), an air pressure sensor, an ultrasonic sensor, and a magnetic sensor, as well as combinations comprising at least one of the foregoing. Additionally, contact sensors with appropriate means contacting the surface 22 in an appropriate manner (i.e. rolling contacts, sliding contacts, etc.) may be employed if they can attain the rates and adjust at the desired tolerances.

For example, the sensor 50 can comprise a triangulation laser arrangement with an emitter and a receiver. To measure the distance of the nozzle 48 from the surface 22, laser light can be projected from the emitter and reflected back to the receiver. Based on the relative positions of the emitter to the receiver, the sensor 50 calculates, by triangulation, the distance of the surface 22 from a reference point of the sensor 50. The height 56 is then calculated by the controller based on the signal from the sensor 50 and a known position of the nozzle 48. As a result, the controller commands the actuator 52 to adjust the nozzle position along the z-axis to compensate for variations in the surface 22. To increase the signal to noise ratio of this and other light based displacement sensors for height measurement, the surface of the support 36 used to hold the partially transparent substrate panel may be coated with an anti-reflective coating such as flat black paint. Other anti-reflective methods may include surface texturing and/or baffling.

Manipulator (e.g., robot arm) 42 can also be configured to compensate for variations in the x-axis and y-axis in order to control the nozzle location with respect to the surface 22 as the grid lines are formed on the panel 24, e.g., has an orientation (rotation X and rotation Y) to match the surface contour. Such an embodiment can be achieved using additional sensor(s) and additional actuator(s) to create the desired relative motion in the x and/or y directions (e.g., to manipulate the nozzle accordingly). For example, at least two additional sensors 50 can measure the positions (x & y-axes) of the surface 22 to determine curvature in the panel. Based on inputs from these sensors, the controller can command the robot arm 42 and/or additional actuator(s) to precisely move the nozzle 48 along the x-axis and/or y-axis, in addition to translating along the z-axis. As a result, the controller can keep the nozzle 48 in a desired relationship to the surface 22 (e.g., normal) at all times as it translates across the panel 24.

Optionally, other components can be used with this system, such as sensor(s), valve(s), connector(s), gauge(s), supply source(s), heater(s), and so forth, as well as combinations comprising at least one of the foregoing. For example, those portions of the apparatus 40 that come into physical contact with the conductive ink (e.g., the paste) can optionally be temperature controlled (e.g., heated and/or cooled) so as to maintain the paste within a predetermined temperature range. For example, these portions can be temperature controlled (heated and/or cooled) to minimize the effect of temperature induced changes in the rheology of the paste. For example, the temperature of the paste can be maintained above room temperature so as to encompass any fluctuations in room temperature, yet below a temperature that would negatively effect the paste (i.e., degrade the paste). In some embodiments, the panel 24, the nozzle 48, the flow regulator 46 and the source of conductive ink 54 are at room temperature (e.g., about 20° C.), but can be heated such as to a temperature of 25° C. to 30° C.

In addition to the above, the system has fixturing to securely hold the panel. Furthermore, the fixturing can provide fiducial marks or datum locators that will create a part-coordinate system in space for robot.

In one embodiment, an apparatus for forming a uniform grid line on a panel comprises: a piston dispenser having a nozzle for dispensing a conductive ink onto a panel, a height sensor in operable communication with the dispenser and positioned to sense the surface of the panel during use at a distance of less than or equal to 5 mm from a point where the nozzle dispenses the conductive ink onto the panel, an actuator configured to create relative motion between the dispenser and the panel, a flow regulator coupled to the conductive ink source so as to regulate a flow rate of conductive ink out of the nozzle during use; and a controller in operational communication with the dispenser, height sensor, actuator, and flow regulator. The nozzle is connected to a conductive ink source. During use, the controller can cause relative motion between the panel and the nozzle, in a predetermined pattern across a surface of the panel in a y-direction, and/or can control the distance in the z-direction between the nozzle and the panel based upon a signal from the height sensor.

A method for forming a conductive trace on a panel can comprise: determining a height between a sensor and a surface of the panel, adjusting the height if the height does not equal a desired height by creating relative motion between the nozzle and the panel, creating relative motion between the nozzle and the panel in the y-direction, and dispensing a conductive ink from the nozzle onto the surface of the panel from a piston dispenser at a rate controlled by a flow regulator to form the conductive trace. The sensor can be in operable communication with a controller and positioned to sense the surface of the panel at a distance of less than or equal to 5 mm from a point where a nozzle dispenses the conductive ink onto the panel. The conductive trace has a uniform width.

In the various embodiments, (i) wherein the distance is less than or equal to 3 mm; and/or (ii) the distance is less than or equal to 1 mm; and/or (iii) the apparatus is capable of forming, within a zone of greater than or equal to 1 meter, a uniform grid line width; and/or (iv) the conductive ink can be dispensed at a rate of greater than or equal to 100 mm/sec; and/or (v) the conductive ink can be dispensed at a rate of greater than or equal to 200 mm/sec; and/or (vi) the height sensor is an ultrasonic sensor; and/or (vii) the rate is only changed while the nozzle traverses a busbar zone; and/or (viii) the rate changes while the nozzle traverses a busbar zone and is maintained constant as the nozzle traverses a non-busbar zone.

All ranges disclosed herein are inclusive of the endpoints, and the endpoints are independently combinable with each other (e.g., ranges of “up to 25 wt. %, or, more specifically, 5 wt. % to 20 wt. %”, is inclusive of the endpoints and all intermediate values of the ranges of “5 wt. % to 25 wt. %,” etc.). “Combination” is inclusive of blends, mixtures, alloys, reaction products, and the like. Furthermore, the terms “first,” “second,” and the like, herein do not denote any order, quantity, or importance, but rather are used to d one element from another. The terms “a” and “an” and “the” herein do not denote a limitation of quantity, and are to be construed to cover both the singular and the plural, unless otherwise indicated herein or clearly contradicted by context. The suffix “(s)” as used herein is intended to include both the singular and the plural of the term that it modifies, thereby including one or more of that term (e.g., the film(s) includes one or more films). Reference throughout the specification to “one embodiment”, “another embodiment”, “an embodiment”, and so forth, means that a particular element (e.g., feature, structure, and/or characteristic) described in connection with the embodiment is included in at least one embodiment described herein, and may or may not be present in other embodiments. In addition, it is to be understood that the described elements may be combined in any suitable manner in the various embodiments.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

I/We Claim:

1. An apparatus for forming a uniform grid line on a panel, the apparatus comprising:
a piston dispenser having a nozzle for dispensing a conductive ink onto a panel, wherein the nozzle is connected to a conductive ink source;
a height sensor in operable communication with the dispenser and positioned to sense the surface of the panel during use at a distance of less than or equal to 5 mm from a point where the nozzle dispenses the conductive ink onto the panel;
an actuator configured to create relative motion between the dispenser and the panel;
a flow regulator coupled to the conductive ink source so as to regulate a flow rate of conductive ink out of the nozzle during use; and
a controller in operational communication with the dispenser, height sensor, actuator, and flow regulator, wherein during use, the controller causes relative motion between the panel and the nozzle a predetermined pattern across a surface of the panel in a y-direction, and controls the distance in the z-direction between the nozzle and the panel based upon a signal from the height sensor.

2. The apparatus of claim 1, wherein the distance is less than or equal to 3 mm.

3. The apparatus of claim 2, wherein the distance is less than or equal to 1 mm.

4. The apparatus of claim 1, wherein the apparatus is capable of forming, within a zone of greater than or equal to 1 meter, a uniform grid line width.

5. The apparatus of claim 1, wherein the conductive ink can be dispensed at a rate of greater than or equal to 100 mm/sec.

6. The apparatus of claim 5, wherein the conductive ink can be dispensed at a rate of greater than or equal to 200 mm/sec.

7. The apparatus of claim 1, wherein the height sensor is an ultrasonic sensor.

8. A method for forming a conductive trace on a panel, comprising:
determining a height between a sensor and a surface of the panel, wherein the sensor is in operable communication with a controller and positioned to sense the surface at a distance of less than or equal to 5 mm from a point where a nozzle dispenses the conductive ink onto the panel;
adjusting the height if the height does not equal a desired height by creating relative motion between the nozzle and the panel;
creating relative motion between the nozzle and the panel in the y direction; and
dispensing a conductive ink from the nozzle onto the surface of the panel from a piston dispenser at a rate controlled by a flow regulator to form the conductive trace;
wherein the conductive trace has a uniform width.

9. The method of claim 8, wherein the distance is less than or equal to 1 mm.

10. The method of claim 9, wherein the rate is greater than or equal to greater than or equal to 100 mm/sec.

11. The method of claim 9, further comprising only changing the rate while the nozzle traverses a busbar zone.

12. The method of claim 9, further comprising changing the rate while the nozzle traverses a busbar zone and maintaining the rate constant as the nozzle traverses a non-busbar zone.
